(19) United States
(12) Patent Application Publication
(10) Pub. No.: US 2018/0130841 A1
(43) Pub. Date: May 10, 2018

(54) IMAGING COMPONENT AND IMAGING MODULE PROVIDED WITH SAME

(71) Applicant: KYOCERA Corporation, Kyoto-shi, Kyoto (JP)

(72) Inventor: Shinji WATANABE, Kirishima-shi (JP)

(73) Assignee: KYOCERA Corporation, Kyoto-shi, Kyoto (JP)

(21) Appl. No.: 15/561,872

(22) PCT Filed: Feb. 25, 2016
(86) PCT No.: PCT/JP2016/055575

§ 371 Date: Sep. 26, 2017

(30) Foreign Application Priority Data
Mar. 27, 2015 (JP) 2015-067248

(51) Int. Cl. H01L 27/146; H05K 1/03; H01L 23/482; H01L 23/498

(52) U.S. Cl. CPC H01L 27/14636; H05K 1/0393; H01L 23/49816; H01L 23/49838; H01L 23/4985; H01L 23/4824

(57) ABSTRACT

An imaging component includes a laminated substrate formed of a resin material; a plurality of electrode pads disposed on an upper face of the laminated substrate, an imaging element being to be mounted on the plurality of electrode pads; and a plurality of conductor patterns which are belt-shaped and disposed between layers of the laminated substrate, the plurality of conductor patterns being connected to the plurality of electrode pads, respectively. A part of at least one of the plurality of conductor patterns has a widened portion, the widened portion being located immediately below any of electrode pads which are not connected to the at least one of the plurality of conductor patterns.

### TECHNICAL FIELD

The present disclosure relates to an imaging component and an imaging module provided with the same.

### BACKGROUND ART

As an imaging component, for example, there is known a camera module described in Japanese Unexamined Patent Publication JP-A 2004-104078 (also referred to as Patent Literature 1, hereinafter). The camera module described in Patent Literature 1 includes: a flexible sheet; and an imaging element mounted on a surface of the flexible sheet.

### CITATION LIST

### Patent Literature

Patent Literature 1: Japanese Unexamined Patent Publication JP-A 2004-104078

### SUMMARY OF INVENTION

The imaging component of the present disclosure includes: a laminated substrate formed of a resin material; a plurality of electrode pads disposed on an upper face of the laminated substrate, an imaging element being to be mounted on the plurality of electrode pads; and a plurality of conductor patterns which are belt-shaped and disposed between layers of the laminated substrate, the plurality of conductor patterns being connected to the plurality of the electrode pads, respectively, a part of at least one of the plurality of conductor patterns having a widened portion, the widened portion being located immediately below any of electrode pads which are not connected to the at least one of the plurality of conductor patterns.

### BRIEF DESCRIPTION OF DRAWINGS

FIG. 1 is a sectional view showing an imaging component and an imaging module;

FIG. 2 is a schematic diagram showing a situation of a surface of a laminated substrate in an imaging component shown in FIG. 1;

FIG. 3 is a schematic diagram showing wiring shapes of conductor patterns in an imaging component shown in FIG. 1;

FIG. 4 is a partial transparent plan view showing an electrode pad and a conductor pattern;

FIG. 5 is a partial transparent plan view showing electrode pads, first portions of conductor patterns, and a laminated substrate;

FIG. 6 is a partial transparent plan view showing an electrode pad and a conductor pattern;

FIG. 7 is a partial transparent plan view showing an electrode pad and a conductor pattern; and

FIG. 8 is a partial transparent plan view showing an electrode pad and a conductor pattern.

### DESCRIPTION OF EMBODIMENTS

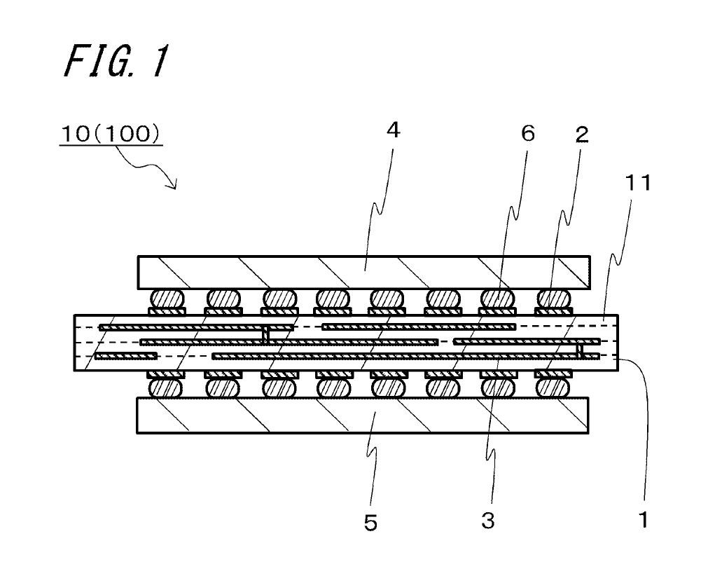

Hereinafter, an imaging component 10 is described below with reference to the drawings. As shown in FIG. 1, the imaging component 10 includes: a laminated substrate 1; electrode pads 2 disposed on an upper face of the laminated substrate 1; and conductor patterns 3 disposed between layers of the laminated substrate 1 and electrically connected to the electrode pads 2. Further, an imaging module 100 includes: the imaging component 10; and an imaging element 4 mounted on the electrode pads 2 of the imaging component 10.

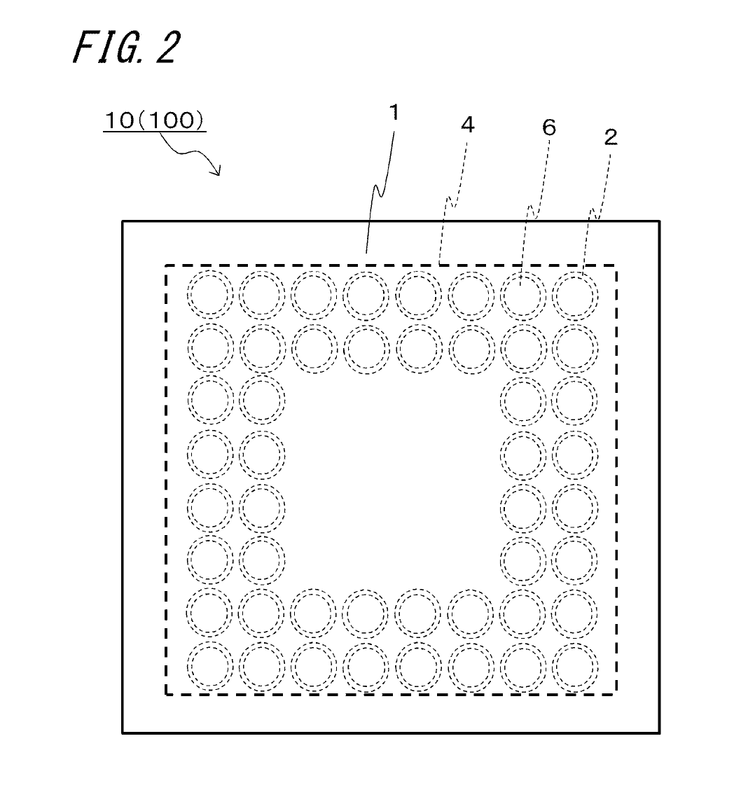

The laminated substrate 1 is formed of a resin material. For example, as the resin material, an epoxy resin is used. Here, the above-mentioned expression “formed of a resin material” does not necessarily indicate that the laminated substrate is formed of a resin material alone. That is, any other material may be contained. Specifically, a so-called glass epoxy which is constituted such that glass fibers are impregnated with an epoxy resin, or the like may be employed. For example, the laminated substrate 1 may be prepared by laminating glass epoxy substrates. As shown in FIG. 2, for example, the laminated substrate 1 has a quadrangular-shaped principal surface and is formed in a plate-like shape. As for the dimensions of the laminated substrate 1, for example, in a case where the laminated substrate 1 has a quadrangular shape, the vertical dimension can be set to 15 to 20 mm, the horizontal dimension can be set to 15 to 20 mm, and the thickness can be set to 0.5 to 2 mm. More specifically, the laminated substrate 1 includes a plurality of layers 11. For example, the thickness of each of the plurality of layers 11 is 0.05 to 0.2 mm.

The electrode pad 2 is a member used for mounting the imaging element 4 on the laminated substrate 1. The plural electrode pads 2 are disposed on the upper face of the laminated substrate 1. As shown in FIGS. 1 and 2, for example, the electrode pad 2 has a rectangular shape in a sectional view and a circular shape in a plan view. Here, FIG. 2 depicts the situation of the surface of the laminated substrate 1 in a state where the imaging element 4, the electrode pads 2, and solder balls 6 are made as if transparent.

For example, the electrode pad 2 is formed of a metallic material such as copper or gold. As for the dimensions of the electrode pad 2, for example, in a case where the electrode pad 2 has a circular shape in a plan view, the diameter can be set to 0.1 to 1 mm and the thickness can be set to 0.01 to 0.05 mm. For example, as the method for mounting the imaging element 4, a ball grid array or otherwise can be adopted. As shown in FIG. 1, in the imaging component 10 of the present disclosure, the imaging element 4 is mounted by a ball grid array and hence a plurality of solder balls 6 are disposed between a lower face of the imaging element 4 and an upper face of the electrode pads 2.

The conductor pattern 3 is a member for transmitting a signal generated by the imaging element 4 mounted on the electrode pads 2, to another electronic component 5 such as a monitor. The conductor pattern 3 is a belt-shaped member. The conductor pattern 3 is disposed between the layers of the laminated substrate 1. For example, the conductor pattern 3 is formed of a metallic material such as copper or gold.

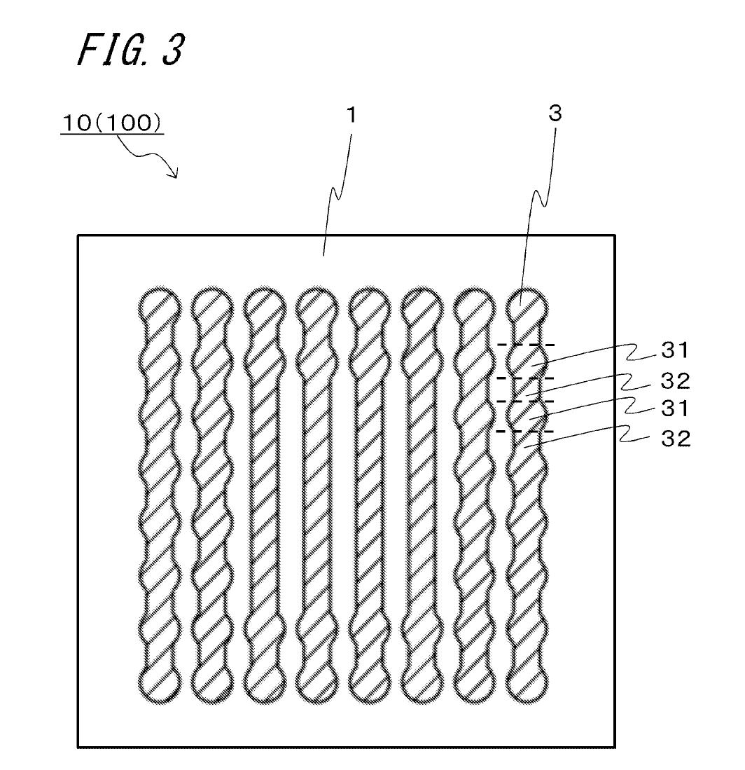

Here, in the imaging component 10 of the present disclosure, as shown in FIGS. 2 and 3, a part of at least one of conductor patterns 3 has a widened portion 31, the widened portion 31 being located immediately below any of electrode pads which are not connected to the at least one of conductor patterns. Here, the above-mentioned “widened portion” indicates a portion whose width is widened partly in the conductor pattern 3 extending with a fixed width. Specifically, as shown in FIG. 3, in a case where the conductor pattern 3 extends in a belt shape, imaginary lines perpendicular to an extension direction of the conductor pattern 3 are drawn at a location where the width of the conductor pattern 3 begins to change when viewed in the extension direction of the conductor pattern 3 and at a location where the width change ends. Then, a region of the conductor pattern 3 located between the two imaginary lines is regarded as the widened portion 31.

In other words, the imaging component 10 includes: the laminated substrate 1 constituted such that the plurality of layers 11 formed of a resin material are laminated; the plurality of electrode pads 2 disposed on the surface of the laminated substrate 1; and the plurality of conductor patterns 3 disposed between the plurality of layers 11. The plurality of conductor patterns 3 have belt shapes. At least one of the plurality of conductor patterns 3 has a first portion 31 and a second portion 32. The first portion 31 overlaps with one of the plurality of electrode pads 2 in a stacking direction of the plurality of layers 11. The second portion 32 does not overlap with the plurality of electrode pads 2 in the stacking direction. The width of the first portion 31 is greater than the width of the second portion 32. The conductor patterns 3 may be formed by printing onto the surfaces of the plurality of layers is performed at the time of lamination of the plurality of layers 11.

Here, in the conductor patterns 3 shown in FIG. 3, for simplicity of understanding, each conductor pattern 3 is intentionally simplified into a straight line shape. The conductor pattern 3 may be formed in a complicated shape. Thus, although FIGS. 2 and 3 are in correspondence to each other, the arrangement of the conductor patterns 3 in FIG. 1 and the arrangement of the conductor patterns 3 in FIG. 3 are not strictly in correspondence to each other. Further, the above-mentioned expression “any of electrode pads 2 which are not connected to the at least one of conductor patterns” does not indicate that the electrode pad 2 and the conductor pattern 3 are completely isolated electrically from each other. Specifically, the expression excludes merely a case where the widened portion 31 of the conductor pattern 3 and the electrode pad 2 located immediately thereabove are directly connected by a through hole or the like. That is, the widened portion 31 and the electrode pad 2 may be indirectly connected through a common power supply or a common ground.

When the portion of the conductor pattern 3 located immediately below the electrode pad 2 has the widened portion 31 as described above, it is possible to reduce a situation that the portion of the laminated substrate 1 immediately below the electrode pad 2 sinks. Further, when in a region other than the portion of the conductor pattern 3 located immediately below the electrode pad 2, the width is made narrower than that of the portion located immediately below the electrode pad 2, high-density routing of the conductor patterns 3 is possible. As a result, the imaging component 10 can be obtained in which the conductor patterns 3 are routed at a high density and yet degradation in the positional accuracy of the imaging element 4 is reduced.

Here, in a transparent plane view, the outer shape of the widened portion 31 may be the same as the outer shape of the electrode pad 2. In other words, when viewed from a direction perpendicular to the surface of the laminated substrate 1, the outer shape of the first portion 31 may be the same as the outer shape of the electrode pad 2 overlapping with the first portion 31. When such a configuration is employed, it is possible to reduce unevenness in the stress in the surface of the conductor pattern 3 transmitted from the electrode pad 2. Then, this can reduce deformation caused in the imaging component 10.

Here, the above-mentioned expression “the shape is the same” indicates that the shape of the portion of the outer shape of the widened portion 31 in directions other than the extension direction of the conductor pattern 3 is the same as the outer shape of the electrode pad. For example, in FIG. 3, the shape of the portion of the outer shape of the widened portion 31 in directions other than the extension direction of the conductor pattern 3 may be regarded as a circular shape. Then, as shown in FIG. 2, the electrode pad 2 has a circular shape. That is, in the present disclosure, the widened portion 31 and the electrode pad 2 are of the same shape.

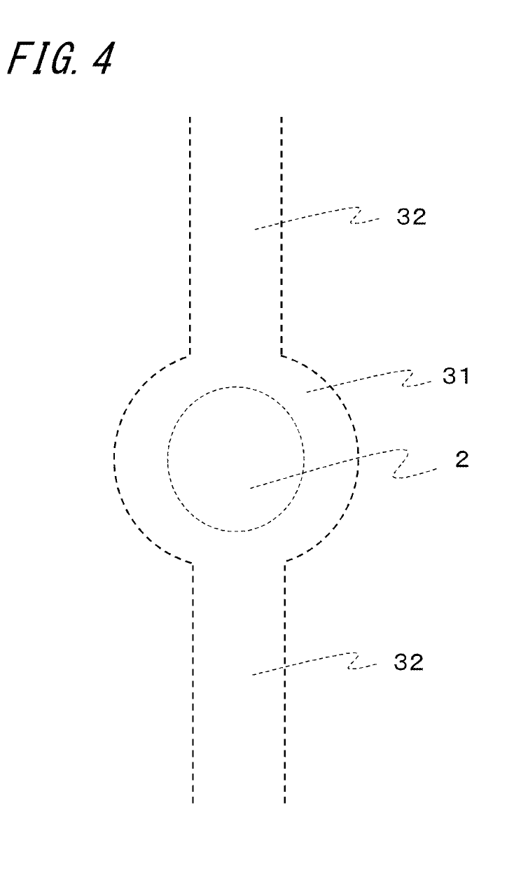

Further, as shown in FIG. 4, the widened portion 31 of the conductor pattern 3 may be wider than the electrode pad 2. In other words, when viewed from the direction perpendicular to the surface of the laminated substrate 1, the first portion 31 may be wider than the electrode pad 2 overlapping with the first portion 31. By virtue of this, even when the deviation in the positional relation between the electrode pad 2 and the conductor pattern 3 is caused under heat cycles, the conductor pattern 3 can be located immediately below the electrode pad 2. More specifically, for example, in a case where the electrode pad 2 has a circular shape in a plan view, it is sufficient that the wide portion of the conductor pattern 3 is formed in a circular shape larger than the electrode pad 2.

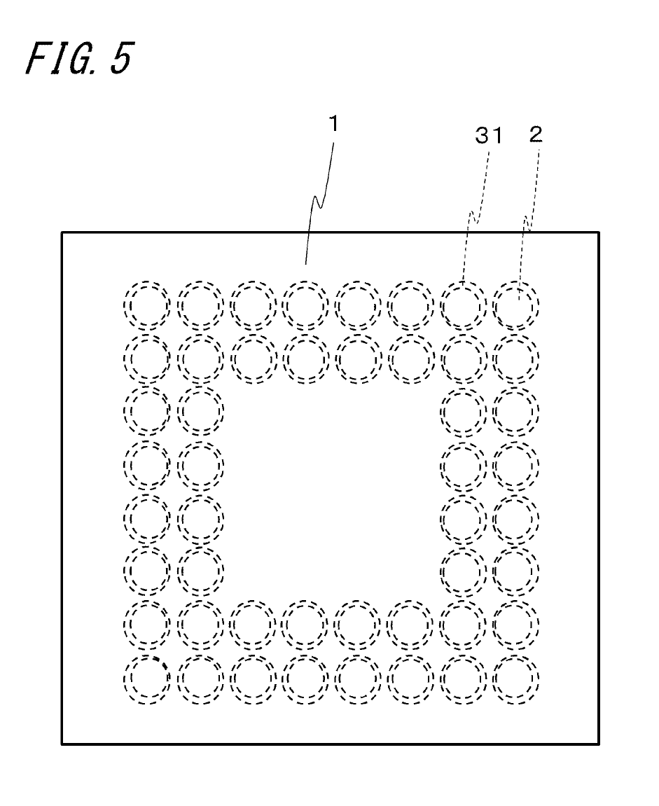

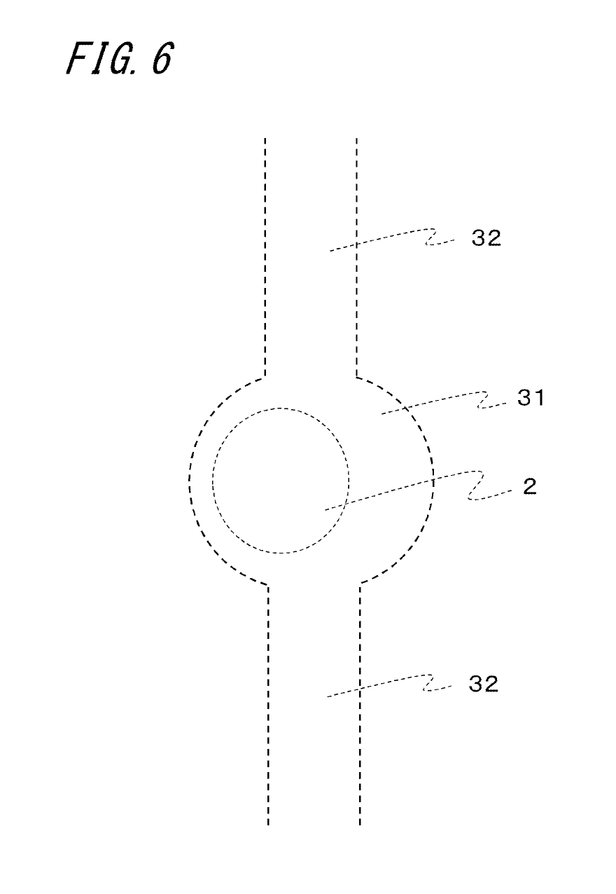

Further, as shown in FIGS. 5 and 6, when viewed from the direction perpendicular to the surface of the laminated substrate 1, the first portion 31 may be wider than the electrode pad 2 overlapping with the first portion 31, and the centroid of each first portion 31 may be located more distant from the centroid of the laminated substrate 1 than from the centroid of each electrode pad 2 overlapping with the first portion 31. In FIG. 5, for simplicity of understanding, the first portions 31 alone of the conductor pattern 3 are shown. More specifically, the centroid of the first portion 31 may be located on an extension line of a straight line joining the centroid of the laminated substrate 1 and the centroid of the electrode pad 2.

Under heat cycles, larger thermal expansion and larger thermal contraction are caused in the surface than in the inside of the laminated substrate 1. In a case where the width of the first portion 31 is made larger than the width of the electrode pad 2 and the centroid thereof is deviated to the outer side of the laminated substrate 1, the electrode pad 2 can easily overlap with the first portion 31 even when the position of the electrode pad 2 deviates under heat cycles.

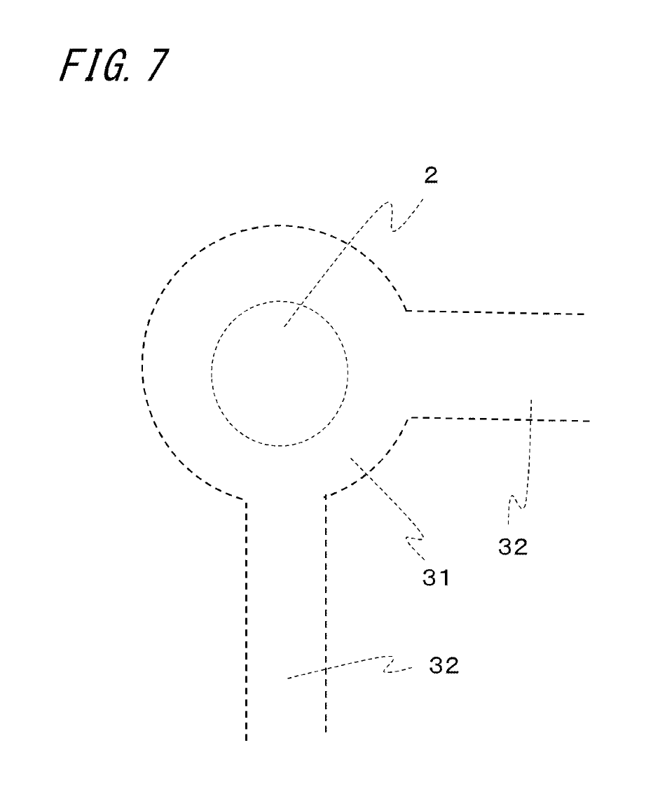

Further, as shown in FIG. 7, the first portion 31 may be located in a bent portion of the conductor pattern 3. In other words, the width of the conductor pattern 3 may be larger in the bent portion of the conductor pattern 3. In general, the bent portion of the conductor pattern 3 is susceptible to a thermal stress from other portions. Specifically, in the straight line portion of the conductor pattern 3, thermal expansion in the length direction is mainly caused. In contrast, the bent portion of the conductor pattern 3 receives a thermal stress from the two straight line portions adjacent to the bent portion. Thus, the direction of occurrence of thermal expansion is difficult to be controlled. Here, as shown in FIG. 7, when the first portion is located in the bent portion of the conductor pattern 3, thermal expansion in the bent portion itself can be made larger. By virtue of this, it is possible to reduce a possibility that a thermal stress caused by thermal expansion of other portions results in thermal expansion of the first portion 31 in an unpredictable direction. This can improve the reliability in the imaging component 10 under heat cycles.

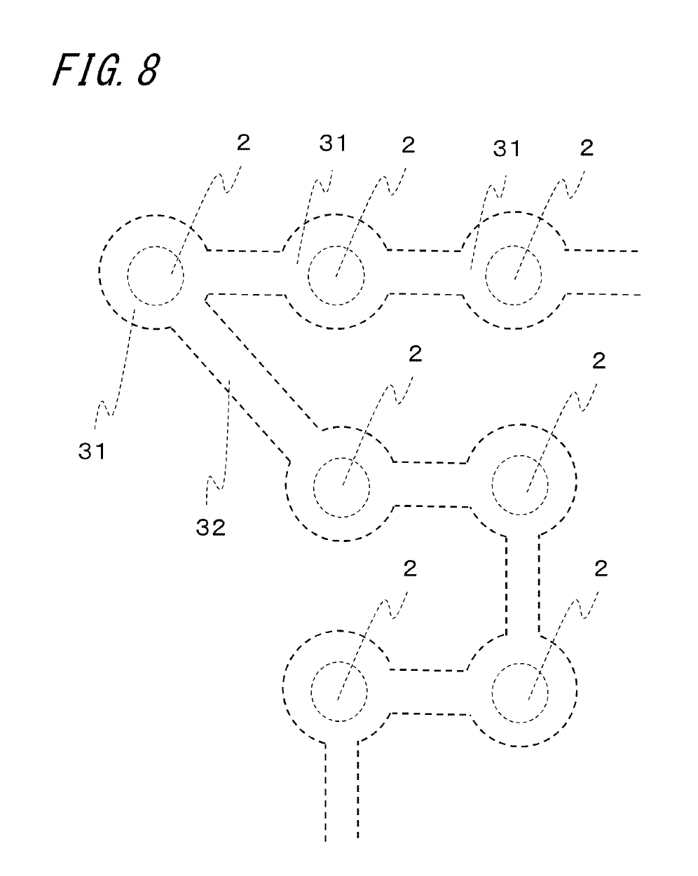

Further, as shown in FIG. 8, adjacent first portions 31 may be arranged at equal intervals. When the first portions 31 are arranged at equal intervals, it is possible to reduce a possibility of unevenness in the thermal expansion amount caused in the laminated substrate 1 under heat cycles. This can reduce a possibility of distortion in the laminated substrate 1.

### REFERENCE SIGNS LIST

1: Laminated substrate

11: Layer

2: Electrode pad

3: Conductor pattern

31: Widened portion

4: Imaging element

5: Electronic component

10: Imaging component

100: Imaging module

1. An imaging component, comprising:
a laminated substrate formed of a resin material;
a plurality of electrode pads disposed on an upper face of the laminated substrate, an imaging element being to be mounted on the plurality of electrodes; and
a plurality of conductor patterns which are belt-shaped and disposed between layers of the laminated substrate, the plurality of conductor patterns being connected to the plurality of electrode pads, respectively,
a part of at least one of the plurality of conductor patterns having a widened portion, the widened portion being located immediately below any of electrode pads which are not connected to the at least one of the plurality of conductor patterns.

2. The imaging component according to claim 1, wherein in a transparent plane view of the imaging component, an outer shape of the widened portion is a same as an outer shape of the electrode pad.

3. An imaging module, comprising:
the imaging component according to claim 1; and
an imaging element mounted on the electrode pads of the imaging component.

4. An imaging component, comprising:
a laminated substrate constituted such that a plurality of layers formed of a resin material are laminated;
a plurality of electrode pads disposed on a surface of the laminated substrate; and
a plurality of conductor patterns disposed between the plurality of layers,
the plurality of conductor patterns having belt shapes, at least one of the plurality of conductor patterns having a first portion and a second portion, the first portion overlapping with one of the plurality of electrode pads in a stacking direction of the plurality of layers, the second portion not overlapping with the plurality of electrode pads in the stacking direction, a width of the first portion being greater than a width of the second portion.

5. The imaging component according to claim 4, wherein when viewed from a direction perpendicular to the surface, an outer shape of the first portion is a same as an outer shape of the one of the plurality of electrode pads overlapping with the first portion.

6. The imaging component according to claim 4, wherein when viewed from a direction perpendicular to the surface, the first portion is wider than the one of the plurality of electrode pads overlapping with the first portion.

7. The imaging component according to claim 6, wherein when viewed from a direction perpendicular to the surface, a centroid of the first portion is located more distant from a centroid of the laminated substrate than from a centroid of the one of the plurality of electrode pads overlapping with the first portion.

8. An imaging module, comprising:
the imaging component according to claim 4; and
an imaging element mounted on the plurality of electrode pads of the imaging component.
